(19) United States
(12) Patent Application Publication
(10) Pub. No.: US 2025/0318125 A1
(43) Pub. Date: Oct. 9, 2025

(54) MEMORY DEVICE STAIRCASE FORMATION

(71) Applicant: Micron Technology, Inc., Boise, ID (US)

(72) Inventors: Srivatsan Venkatesan, Hyderabad (IN); Kalyan Chakravarthy Kavalipurapu, Hyderabad (IN)

(21) Appl. No.: 19/087,235

(22) Filed: Mar. 21, 2025

Related U.S. Application Data
(60) Provisional application No. 63/575,498, filed on Apr. 5, 2024.

(51) Int. Cl. H10B 43/27; H10B 41/27

(52) U.S. Cl. CPC H10B 43/27; H10B 41/27

(57) ABSTRACT

Methods, systems, and devices for memory device staircase formation are described. A memory device may include a stack of materials that includes a first staircase portion, at a first surface of the stack, having first contact surfaces for a first subset of word lines and a second staircase portion, at a second surface of the stack, which includes second contact surfaces for a second subset of the word lines. Conductive pillars may couple the word lines of the first subset and the second subset to the supporting circuitry. For example, a first conductive pillar may extend, in a first plane, from a first word line of the first subset toward the first surface of the stack and a second conductive pillar may extend, in the first plane, from a second word line of the second subset toward the second surface of the stack.

### CROSS REFERENCE

The present Application for Patent claims priority to U.S. Patent Application No. 63/575,498 by Venkatesan et al., entitled “MEMORY DEVICE STAIRCASE FORMATION,” filed Apr. 5, 2024, which is assigned to the assignee hereof, and which is expressly incorporated by reference in its entirety herein.

### TECHNICAL FIELD

The following relates to one or more systems for memory, including memory device staircase formation.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports memory device staircase formation in accordance with examples as disclosed herein.

FIG. 2 shows an example of a memory architecture that supports memory device staircase formation in accordance with examples as disclosed herein.

FIG. 3 shows an example of a block diagram that supports memory device staircase formation in accordance with examples as disclosed herein.

FIG. 4 shows an example of an architecture that supports memory device staircase formation in accordance with examples as disclosed herein.

FIGS. 5A-5H show examples of processes that support memory device staircase formation in accordance with examples as disclosed herein.

FIGS. 6A and 6B show examples of processes that support memory device staircase formation in accordance with examples as disclosed herein.

FIG. 7 shows a flowchart illustrating a method or methods that support memory device staircase formation in accordance with examples as disclosed herein.

### DETAILED DESCRIPTION

Some memory technologies may stack memory cells in different layers to achieve higher densities of memory cells per die area. In these memory technologies (such as not-and (NAND) memory devices), an area may be used for memory cells and other areas may be used to connect the various layers of the memory cells and the circuitry that support the memory cells (e.g., decoders, sense amplifiers, drivers, and other circuitry). For example, a staircase area may be configured to connect metal layers that act as word lines with the supporting circuitry. In the staircase area, different metal layers may be exposed and individually coupled with the circuitry. Given the high quantity of layers, such an area may resemble a staircase because different connectors are coupled with different layers. A staircase structure may be utilized to form (e.g., expose) contact surfaces for each word line of the set of word lines (e.g., for word lines that may be relatively lower in the stack than others), and the contact surfaces may be used as landing pads for conductive pillars that couple each word line with circuitry for accessing memory cells of the memory array. Each tier of the staircase may correspond to a respective word line of the set of word lines.

The staircase area may couple to each word line in a systematic manner such that each word line contact has a respective depth (e.g., tier). For example, a first word line contact may be at a relatively shallow depth, a second word line contact may be at a relatively deeper depth than the first word line, and so on. To couple the word lines with supporting circuitry (e.g., circuitry for accessing memory cells coupled with the word lines), conductive pillars may be coupled with the word line contacts and may extend through the stack of materials. Each conductive pillar may have a respective length based on a corresponding depth of the word line contact. Staircases formed in this manner may occupy a relatively large area in a memory system.

In accordance with examples described herein, a double-sided staircase may utilize a smaller area (e.g., a relatively smaller footprint) than a single-sided staircase architecture. In a single-sided staircase architecture, a single word line contact may be positioned at a given location. In a double-sided staircase architecture, two contacts may be positioned at a given location, a first contact extending away from a first word line in a first direction and a second contact extending away from a second word line in a second direction opposite from the first direction. For example, the double-sided staircase may include a first staircase portion that includes first contact surfaces for a first subset of the word lines. A second staircase portion includes second contact surfaces for a second subset of word lines that are positioned opposite the first contact surfaces. Conductive pillars may couple the word lines of the first subset and the second subset to the supporting circuitry. The double-sided staircase may utilize relative less space than a single-sided staircase, which may result in the associated memory array having a relatively smaller footprint, which may support increased efficiency or accuracy of memory access or may support a greater capacity of an associated memory array, among other advantages.

In addition to applicability in memory systems as described herein, techniques for memory device staircase formation may be generally implemented to improve the efficient use of space in a memory die. Efficiently using the die area may enable higher densities of memory that may enable improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving memory a capacity of some memory devices, which may decrease processing or latency times, improve response times, or otherwise improve user experience, among other benefits.

Features of the disclosure are illustrated and described in the context of memory devices and arrays. Features of the disclosure are further illustrated and described in the context of block diagrams, architectures, processes, and flowcharts.

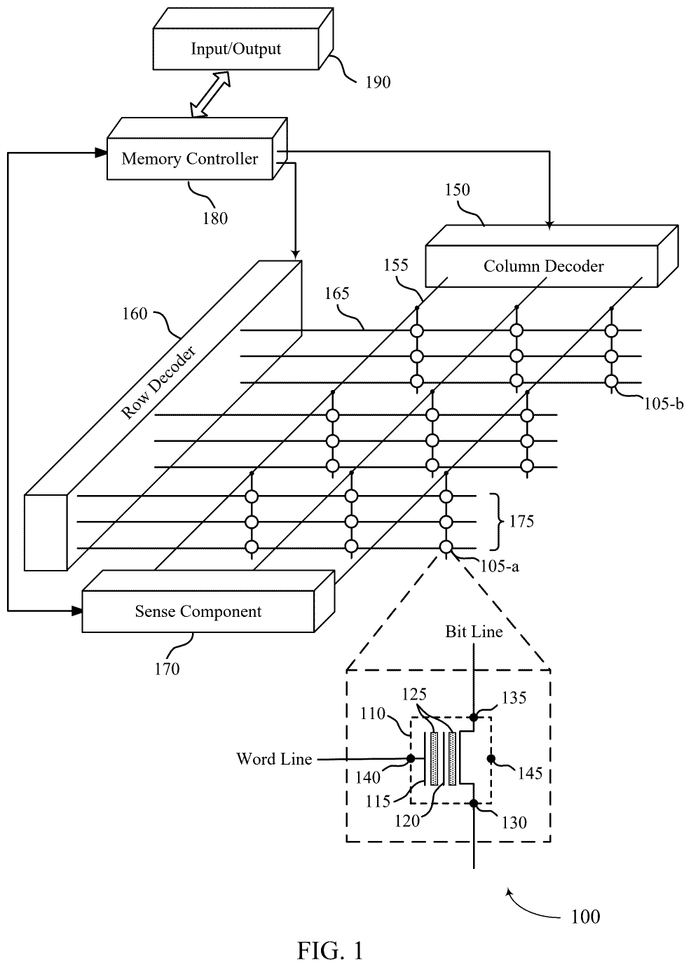

FIG. 1 shows an example of a memory device 100 that supports memory device staircase formation in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120 or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another and may be generically referred to as access lines or select lines.

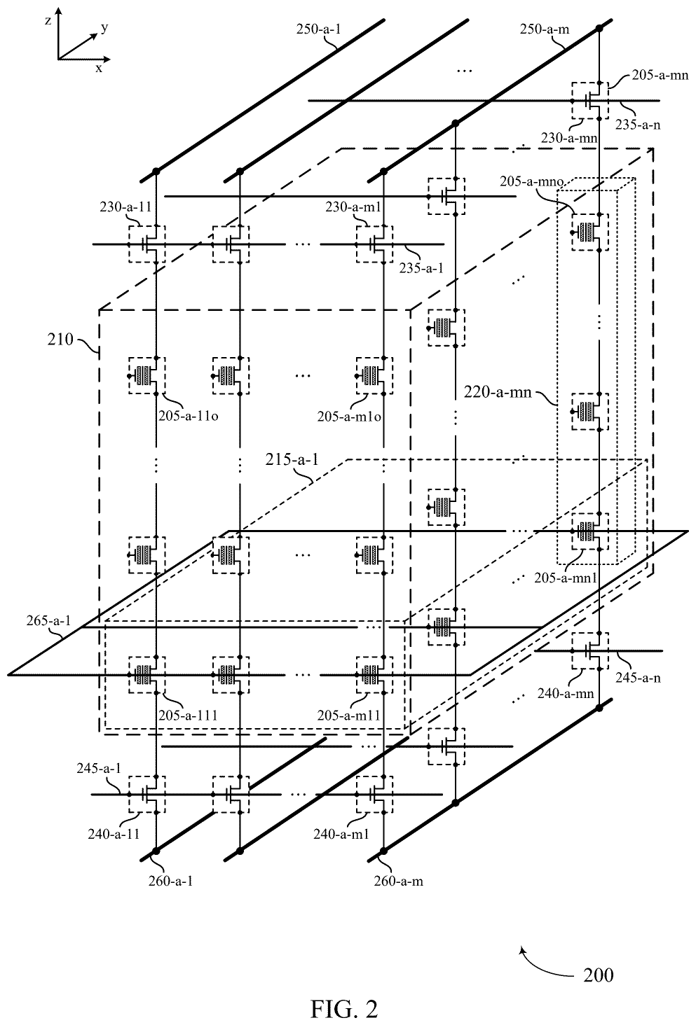

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In accordance with examples described herein, a double-sided staircase may be formed, which may utilize a smaller area (e.g., a relatively smaller footprint) than a single-sided staircase architecture. For example, the double-sided staircase may include a first staircase portion that includes first contact surfaces for a first subset of the word lines 165. The first staircase portion may be formed at a first surface of the stack of materials. The stack of materials may be rotated to expose a second surface (e.g., a surface opposite the first surface), and a second staircase portion that includes second contacts for a second subset of the word lines 165 may be formed at the second surface of the stack of materials. Conductive pillars may couple the word lines 165 of the first subset and the second subset to the supporting circuitry. The double-sided staircase may utilize relatively less space than a single-sided staircase, which may result in the associated memory device 100 having a relatively smaller footprint, which may support increased efficiency or accuracy of memory access or may support a greater capacity of an associated memory array, among other advantages.

The memory device 100 may include any quantity of non-transitory computer readable media that support memory device staircase formation. For example, a memory controller 180, a row decoder 160, a column decoder 150, a sense component 170, or an input/output component 190, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

FIG. 2 shows an example of a memory architecture 200 that supports memory device staircase formation in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1) and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

In accordance with examples described herein, a double-sided staircase may be formed, which may utilize a smaller area (e.g., a relatively smaller footprint) than a single-sided staircase architecture. For example, the double-sided staircase may include a first staircase portion that includes first contact surfaces for a first subset of word lines 265. The first staircase portion may be formed at a first surface of the stack of materials. The stack of materials may be rotated to expose a second surface (e.g., a surface opposite the first surface), and a second staircase portion that includes second contacts for a second subset of the word lines 265 may be formed at the second surface of the stack of materials. Pillars (e.g., conductive pillars) may couple the word lines 265 of the first subset and the second subset to supporting circuitry. The double-sided staircase may utilize relatively less space than a single-sided staircase, which may result in the associated memory device having a relatively smaller footprint, which may support increased efficiency or accuracy of memory access or may support a greater capacity of an associated memory array, among other advantages.

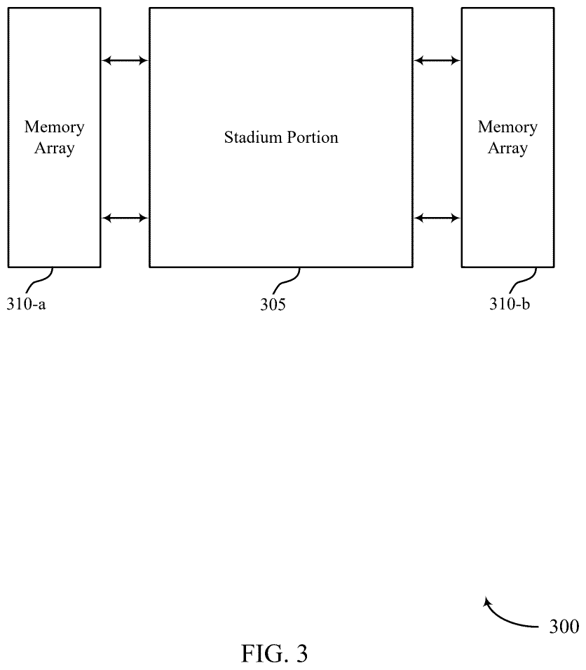

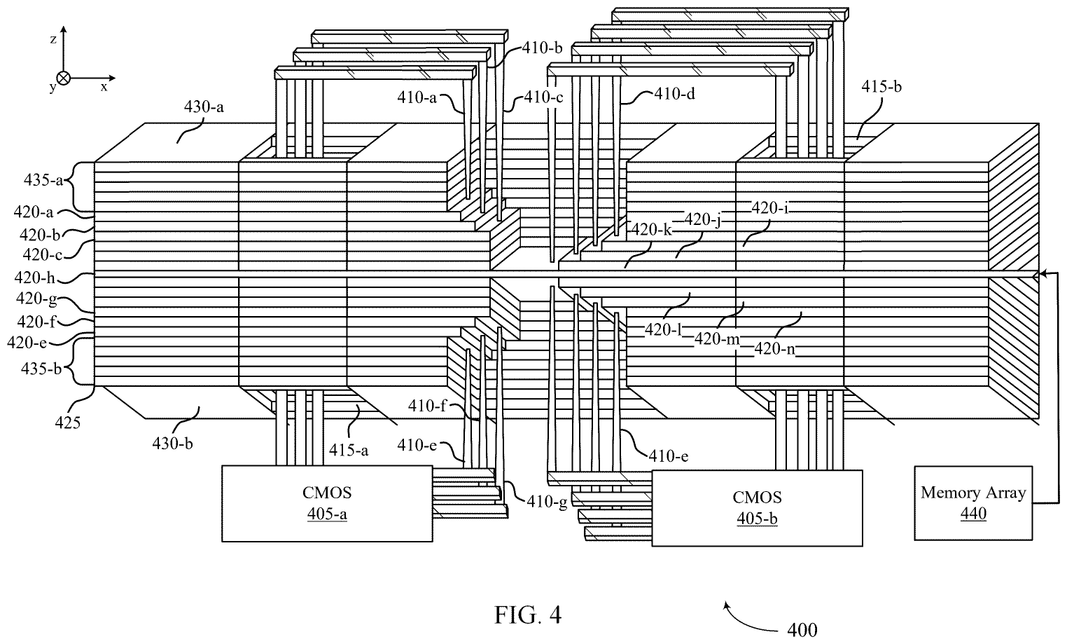

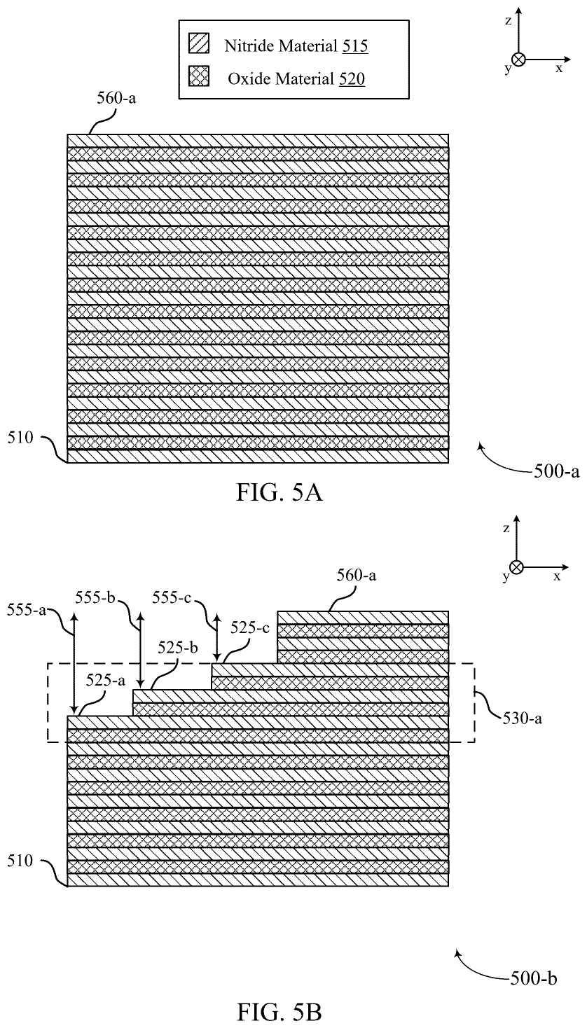

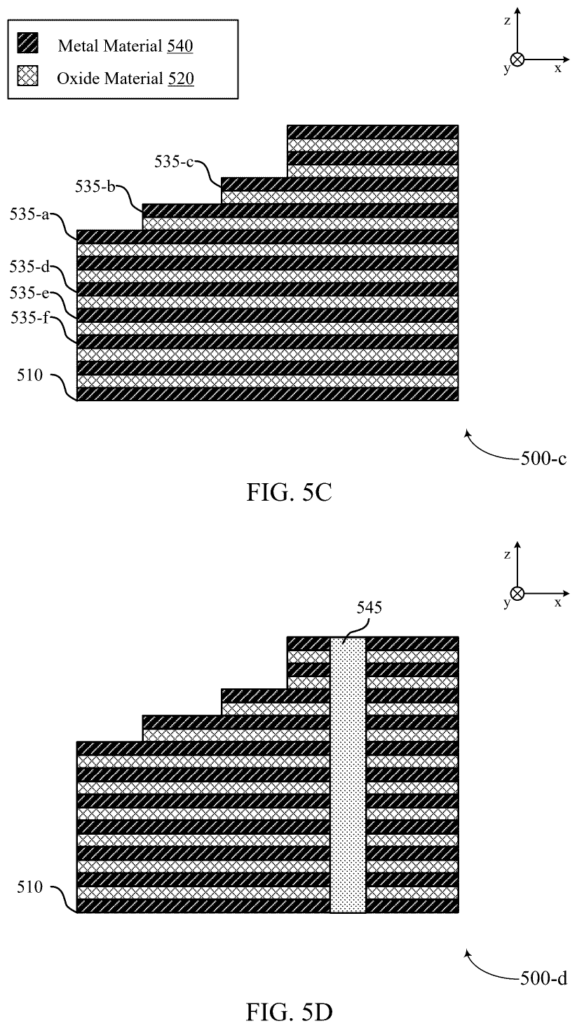

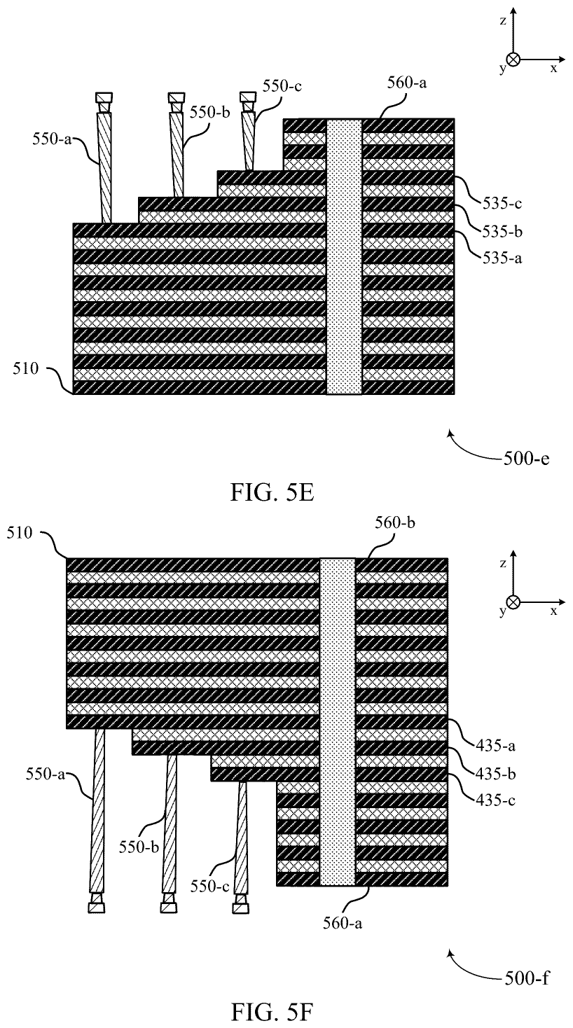

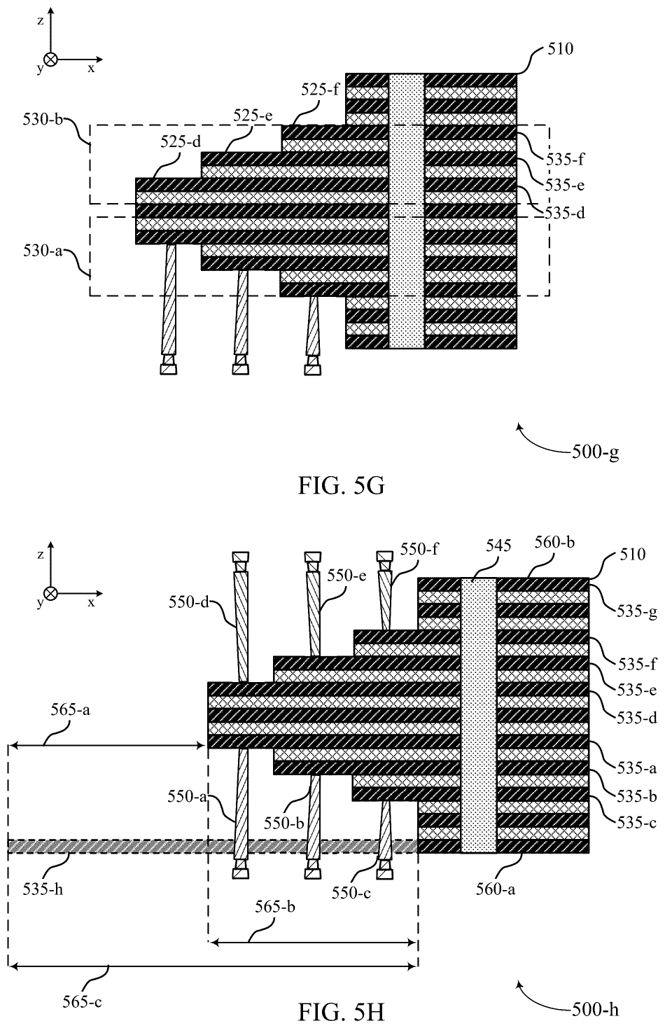

FIG. 3 shows an example of a block diagram that supports memory device staircase formation in accordance with examples as disclosed herein. The block diagram 300 may illustrate a stadium portion 305 coupled with one or more memory arrays 310. For example, the stadium portion 305 may be coupled with a first memory array 310-a and a second memory array 310-b. The block diagram 300 may represent a portion of a structure (e.g., a stadium portion having one or more staircase regions) formed by the processes 500 described herein with respect to FIGS. 5A-5B. The staircase regions of the stadium portion may utilize relatively less space than a single-sided staircase, which may result in the associated memory device having a relatively smaller footprint, which may support increased efficiency or accuracy of memory access or may support a greater capacity of the associated memory arrays 310, among other advantages.

The stadium portion 305 may include one or more staircase portions that include contact surfaces for respective word lines. For example, the stadium portion 305 may include one or more (e.g., two) staircase portions mirrored across the z-axis (e.g., as described in greater detail with reference to FIG. 4). The two staircase portions of the stadium may each be formed at different depths to form contact surfaces of different word lines. The word lines may be coupled with the memory arrays 310, as well as respective conductive pillars. That is, a first end (e.g., a first portion) of the word lines may include contact surfaces for coupling with respective conductive pillars. A second end (e.g., a second portion) of the word lines may be coupled with one or more memory cells of the respective memory arrays 310. The stadium portion 305 may allow for the conductive pillars to be coupled with supporting circuitry (e.g., a complementary metal oxide semiconductor (CMOS)) while occupying a relatively small footprint.

FIG. 4 shows an example of an architecture 400 that supports memory device staircase formation in accordance with examples as disclosed herein. The architecture 400 may implement or may be implanted by aspects of the memory device 100 or the memory architecture 200. For example, the architecture 400 may include word lines 420, which may be examples of word lines 265 as described with reference to FIGS. 2 and 3, and conductive pillars 410, which may be examples of pillars as described with reference to FIGS. 2 and 3. The architecture 400 may be utilized in one or more memory device architectures. The architecture 400 may be implemented in a 3D NAND architecture. Alternatively, these techniques may be implemented in other technologies such as 3D DRAM, vertical memory architectures (e.g., VIX), or other memory architectures. The stadium structure illustrated in FIG. 4 may allow for conductive pillars 410 to be coupled with supporting circuitry (e.g., a complementary metal oxide semiconductor (CMOS)) while occupying a relatively small footprint.

The architecture 400 may include a first staircase portion, which may include respective contact surfaces for a first subset of word lines 420 that includes a word line 420-a, a word line 420-b, and a word line 420-c. The first staircase portion may be an example of a staircase portion. For example, the first staircase portion may be formed (e.g., etched), at least in part, by a process 500-b, among other processes 500, as described with reference to FIG. 5B. The architecture 400 may also include a second staircase portion, which may include respective contact surfaces for a second subset of word lines 420 that includes a word line 420-e, a word line 420-f, and a word line 420-g. The second staircase portion may be an example of the staircase portion. For example, the second staircase portion may be formed, at least in part, by the process 500-g, among other processes, as described with reference to FIG. 5G.

In some examples, the architecture 400 may illustrate one or more stadium portions. Stadium portions may be (or otherwise refer to) cavities (e.g., a generally rectangular shape with dimensions in the x, y, and z directions) that, when combined with one or more staircase portions, make up a stadium region that includes contact surfaces for multiple layers (e.g., word lines 420) of the stack 425. Formation of the architecture 400 may include etching a first stadium portion into a surface 430-a of the stack 425. The first stadium portion may be etched to a first depth (e.g., half the height of the stack 425 in the z-direction) corresponding to a word line 420-h.

Staircase portions may be located on either side of the first stadium portion and may be included in a first stadium region that includes multiple tiers. For example, the first staircase portion may be located on a first side (e.g., relative to the x-direction) of the first stadium region and may include respective contact surfaces of the word line 420-a, the word line 420-b, and the word line 420-c. The respective contact surfaces may support coupling of the word line 420-a, the word line 420-b, and the word line 420-c with a CMOS 405-a via one or more conductive pillars 410. For example, the conductive pillar 410-a may form a conductive path (e.g., which may extend through a via 415-a) to couple the word line 420-a with the CMOS 405-a.

A third staircase portion may be located on a second side (e.g., relative to the x-direction) of the first stadium portion and may include respective contact surfaces of the word line 420-i, the word line 420-j, and the word line 420-k. The third staircase portion may be an example of a staircase portion. The third staircase portion may be flipped over the z-axis relative to the first staircase portion. The respective contact surfaces may support coupling of the word line 420-i, the word line 420-j, and the word line 420-k with a CMOS 405-b via one or more conductive pillars 410. For example, the conductive pillar 410-d may form a conductive path (e.g., which may extend through a via 415-b) to couple the word line 420-i with the CMOS 405-b.

A fourth staircase portion may be located on the second side (e.g., relative to the x-direction) of the third stadium portion and may include respective contact surfaces of the word line 420-l, the word line 420-m, and the word line 420-n. The third staircase portion may be an example of a staircase portion. The third staircase portion may be flipped over the z-axis relative to the second staircase portion. The respective contact surfaces may support coupling of the word line 420-l, the word line 420-m, and the word line 420-n with a CMOS 405-b via one or more conductive pillars 410. For example, the conductive pillar 410-e may form a conductive path to couple the word line 420-m with the CMOS 405-b.

The architecture 400 may also include a second stadium portion on a surface 430-b of the stack 425. The second stadium portion may have a second depth the same as the first depth of the first stadium region but may be flipped over the z-axis relative to the first stadium portion. The architecture 400 may include staircase portions on either side of the second stadium portion. For example, the second staircase portion may be located on a first side (e.g., relative to the x-direction) of the second stadium portion and may include respective contact surfaces of the word line 420-e, the word line 420-f, and the word line 420-g. A fourth staircase portion may be located on a second side (e.g., relative to the x-direction) of the second stadium portion and may include respective contact surfaces of the word line 420-l, the word line 420-m, and the word line 420-n. The fourth staircase portion may be located about the z-axis relative to the second staircase portion.

The conductive pillar 410-a may be coupled with the word line 420-a. The conductive pillar 410-a may extend, in a first plane (e.g., vertical plane, a zy-plane), from the word line 420-a toward a surface 430-a of the stack 425. A conductive pillar 410-e may be coupled with a word line 420-e. The conductive pillar 410-e may extend, in the first plane (e.g., vertical plane, the zy-plane) from the word line 420-e toward a surface 430-b of the stack 425 opposite the surface 430-a. In some examples, the conductive pillar 410-a and the conductive pillar 410-e may be coplanar (e.g., positioned on a common vertical plane, or a common zy-plane), may be vertically aligned, or both.

The conductive pillar 410-a may be included in the first set of conductive pillars 410 that includes the conductive pillar 410-a, a conductive pillar 410-b, and a conductive pillar 410-c. Each of the first set of conductive pillars 410 may be coupled with a respective tier (e.g., word line 420) of a first set of tiers of a first staircase portion (e.g., as described in greater detail with reference to FIGS. 5A-H). The first set of tiers may be associated with (e.g., correspond to) a first subset of word lines 420 that includes the word line 420-a, a word line 420-b, and a word line 420-c. For example, the conductive pillar 410-a may be coupled with the word line 420-a, the conductive pillar 410-b may be coupled with the word line 420-b, and the conductive pillar 410-c may be coupled with the word line 420-c.

The conductive pillar 410-e may be included in a second set of conductive pillars 410 that includes the conductive pillar 410-e, a conductive pillar 410-f, and a conductive pillar 410-g. Each of the second set of conductive pillars 410 may be coupled with a respective tier (e.g., word line 420) of a second set of tiers of a second staircase portion. The second set of tiers may be associated with (e.g., correspond to) a second subset of word lines 420 that includes the word line 420-e, a word line 420-f, and a word line 420-g. For example, the conductive pillar 410-e may be coupled with the word line 420-e, the conductive pillar 410-f may be coupled with the word line 420-f, and the conductive pillar 410-g may be coupled with the word line 420-g.

In some examples, the architecture 400 may include one or more memory arrays of memory cells. A memory array 440 may include one or more memory cells that are coupled with one or more word lines 420 of the first subset of word lines 420. For example, the memory array 440 may include a first portion (e.g., a first array portion) that is coupled with the word line 420-a, a word line 420-b, and a word line 420-c. The memory array 440 may also include a second portion (e.g., a second array portion) that is coupled with one or more word lines 420 of the second subset of word lines 420. For example, the second portion may be coupled with the word line 420-e, the word line 420-f, and the word line 420-g. In some instances, each word line 420 may be coupled with a column of memory cells of the memory array 440, and each memory cell may be coupled with a respective bit line (not shown).

The architecture 400 may also include a second memory array (not shown) that is coupled with a second subset of word lines 420. For example, the second memory array may include a third portion (e.g., a third array portion) that is coupled with a third subset of word lines 420 that includes the word line 420-i, the word line 420-j, and the word line 420-k. The second memory array may also include a fourth portion (e.g., a fourth array portion) that is coupled with a fourth subset of word lines 420 that includes the word line 420-l, the word line 420-m, and the word line 420-n. In some instances, each word line 420 may be coupled with a column of memory cells of the second memory array, and each memory cell may be coupled with a respective bit line (not shown).

The architecture 400 may include a CMOS 405-a (e.g., circuitry) to access memory cells (e.g., the first set of memory cells, the second set of memory cells). The CMOS 405-a may be positioned adjacent to the surface 430-b. The CMOS 405-a may be coupled with each of the first set of conductive pillars 410, including the conductive pillar 410-a, the conductive pillar 410-b, and the conductive pillar 410-c, and to each of the second set of conductive pillars 410, including the conductive pillar 410-e, the conductive pillar 410-f, and the conductive pillar 410-g. Because the conductive pillar 410-e extends toward the surface 430-b of the stack 425 and the CMOS 405-a is adjacent to (e.g., below) the surface 430-b, the conductive pillar 410-e may be coupled with the CMOS 405-a without a via 415-a. However, the conductive pillar 410-a may extend in a direction opposite the conductive pillar 410-e toward the surface 430-a, which is opposite the surface 430-b. To support coupling of the conductive pillar 410-a with the CMOS 405-a, the architecture 400 may include a via 415-a (e.g., a through dielectric via 415, a through area) that extends through the stack 425. The conductive pillar 410-a may be coupled with the CMOS 405-a through the via 415-a. The architecture 400 may also include a CMOS 405-b to access other memory cells (e.g., the third set of memory cells, the fourth set of memory cells).

The word line 420-a and the word line 420-e may extend along the x-direction. The conductive pillar 410-a may extend (e.g., through the stack 425) in along the z-direction in a first direction toward the surface 430-a, and the conductive pillar 410-e may extend (e.g., through the stack 425) along the z-direction in a second direction opposite the first direction toward the surface 430-b. The conductive pillar 410-a may have a first length in the z-direction and the word line 420-a may have a second length in the x-direction.

In some examples, the conductive pillar 410-b may be coupled with the word line 420-b. The word line 420-b may extend in the x-direction (e.g., parallel to the word line 420-a and the word line 420-e). The conductive pillar 410-b may extend along the z-direction in the first direction toward the surface 430-a (e.g., parallel to the conductive pillar 410-a). The word line 420-b may have a third length different from (e.g., greater than) the second length of the word line 420-a. The conductive pillar 410-b may have a fourth length different from (e.g., greater than) the first length of the conductive pillar 410-a.

The conductive pillar 410-c may have a fifth length and the word line 420-e may have a sixth length. In some examples, the conductive pillar 410-f may be coupled with the word line 420-f. The word line 420-f may extend in the x-direction (e.g., parallel to the word line 420-a, the word line 420-b, and the word line 420-c). The conductive pillar 410-f may extend along the z-direction in the second direction toward the surface 430-b (e.g., parallel to the conductive pillar 410-e). The word line 420-f may have a seventh length different from (e.g., greater than) a sixth length of the word line 420-e. The conductive pillar 410-f may have an eighth length different from (e.g., greater than) a fifth length of the conductive pillar 410-e.

FIGS. 5A-5H show examples of processes 500 that support memory device staircase formation in accordance with examples as disclosed herein. The processes 500 may implement or may be implanted by aspects of the memory device 100 or the memory architecture 200. For example, the processes 500 may support formation of word lines 535, which may be examples of word lines 265 as described with reference to FIGS. 2 and 3, and of conductive pillars 550, which may be examples of pillars as described with reference to FIGS. 2 and 3. The processes 500 may be utilized 3D NAND memory architectures. Alternatively, the processes 500 may be utilized for 3D DRAM, VIX, or other memory architectures. Elements of the processes 500 may be described relative to an x-direction, a y-direction, and a z-direction, as illustrated in each of FIGS. 5A-5H. In some examples, the processes 500 may be performed in the order that they are described. However, the processes 500 described herein describe possible implementations, and the operations and the steps associated with the processes 500 may be rearranged or otherwise modified and other implementations are possible. Further, portions from two or more of the processes 500 may be combined.

A process 500-a may include forming a stack 510 of materials. In some examples, the stack 510 of materials may include an oxide material 520 and a nitride material 515. For example, the stack 510 of materials may include alternating layers of an oxide material 520 and a nitride material 515. The oxide material 520 may include iron oxide, aluminum oxide, or zinc oxide, or a combination thereof, among other oxide materials. The nitride material 515 may include silicon, beryllium nitride, aluminum nitride, or gallium nitride, or a combination thereof, among other nitride materials. In some examples, the alternating layers of the oxide material 520 and the nitride material 515 may extend along the x-direction.

A process 500-b may include etching a first side (e.g., a surface 560-a) of a stack 510. Etching the surface 560-a of the stack 510 may form a first staircase portion 530-a that includes a first set of tiers 525 including a tier 525-a, a tier 525-b, and a tier 525-c. As used herein, a tier 525 may refer to a respective level of the stack 510. The tiers 525 may each include one or more layers of the nitride material 515 and the oxide material 520. At other processes 500 (e.g., at processes 500-b through 500-h), the tiers 525 may each include one or more layers of other materials (e.g., a layer of a metal material corresponding to a word line 535).

The process 500-b may include exposing a respective surface of each tier 525 of the first set of tiers 525. The respective surfaces of each tier 525 may be contact surfaces, which may be used (e.g., at process 500-e, as described with reference to FIG. 5E) as landing pads for conductive pillars 550 that couple each tier 525 (e.g., each word line 535) with supporting circuitry. Each tier 525 of the first set of tiers 525 may be located at (e.g., associated with) a respective depth 555 (e.g., a different depth 555) relative to the surface 560-a of the stack 510. For example, the tier 525-a may be located at a depth 555-a, the tier 525-b may be located at a depth 555-b, and the tier 525-c may be located at a depth 555-c.

A process 500-c may include forming a set of word lines 535. The set of word lines 535 may be formed by replacing the nitride material 515 with a metal material. Such a process of replacing the nitride material 515 with a metal material may be referred to as a replacement gate process or a metallization process. The process 500-c may include removing (e.g., etch, selectively etch) the nitride material 515 from the stack 510. In some examples, removing the nitride material 515 from the stack 510 may form a set of cavities (e.g., a set of horizontal cavities extending along the x-direction), and the metal material may be deposited in each cavity of the set of cavities to form a set of metal layers. Each metal layer of the set of metal layers may correspond to a word line 535. The metal material may include tungsten (W), or any other conductive material.

A first subset of the set of word lines 535 (e.g., word lines 535 associated with the staircase portion 530-a) may include a word line 535-a, a word line 535-b, and a word line 535-c, among others. The word line 535-a may correspond to (e.g., be located at) the tier 525-a, the word line 535-b may correspond to (e.g., be located at) the tier 525-b, and the word line 535-c may correspond to (e.g., be located at) the tier 525-c. A tier 525 may include one or more layers of the metal material and the oxide material 520, and a word line 535 corresponding to each tier 525 may be composed of the metal material. A second subset of the set of word lines 535 (e.g., word lines associated with a staircase portion 530-b) may include a word line 535-d, a word line 535-e, and a word line 535-f. The second subset of word lines 535 may, at some later point in time (e.g., at process 500-g), be associated with a second staircase portion 530-b, as described with reference to FIG. 5G.

A process 500-d may include etching through the surface 560-a of the stack 510 to form a via 545 (e.g., a through dielectric via 545, a through area, a hole). The via 545 may extend along the z-direction (e.g., parallel to one or more conductive pillars 550, orthogonal to a surface 560-b of the stack 510). The via 545 may have a width in the z-direction that is less than a width of the stack 510 in the z-direction (e.g., such that word lines 535, which may extend along the x-direction in the xy-plane, may be contiguous along the x-direction). In some examples, the process 500-d may include forming multiple vias 545. The multiple vias 545 may be distributed along the y-direction, along the x-direction, or both. In some examples, the process 500-d may include wet etching or dry etching through the surface 560-a. For wet etching, an etchant may be selected such that the etchant may selectively remove portions of the stack 510 (e.g., and not others). In some examples, the process 500-d may be performed before the process 500-e, and in other examples, the process 500-d may be performed after the process 500-e.

A process 500-e may include forming a first set of conductive pillars 550 including a conductive pillar 550-a, a conductive pillar 550-b, and a conductive pillar 550-c, among other conductive pillars 550. The first set of conductive pillars 550 may be coupled with the first subset of the set of word lines 535. For example, the conductive pillar 550-a may be coupled with the word line 535-a, the conductive pillar 550-b may be coupled with the word line 535-b, and the conductive pillar 550-c may be coupled with the word line 535-c. In some examples, the process 500-e may be performed after the process 500-d, and in other examples, the process 500-e may be performed before the process 500-d.

Each conductive pillar 550 of the first set of conductive pillars 550 may extend from a respective tier 525 of the first set of tiers 525 along the z-direction toward a surface 560-a (e.g., an upper surface 560-a) of the stack 510. In an example, the conductive pillar 550-a may extend from the tier 525-a along the z-direction toward the surface 560-a of the stack 510. In some examples, the process 500-e may include forming a first conductive path between each of the first set of conductive pillars and circuitry (e.g., CMOS) 605, as described with reference to FIG. 4) to access memory cells. The circuitry may be adjacent to the surface 560-a and may be formed (e.g., between processes 500-e and 500-f) using a wafer-on-wafer bonding technique.

A process 500-f may include rotating the stack 510 such that a second side (e.g., a surface 560-b, a bottom surface 560-b) of the stack 510 is exposed for processing. In some examples, the stack 510 may be rotated approximately 180 degrees such that the surface 560-b is exposed. In other examples, the stack 510 may be rotated slightly more or slightly less than 180 degrees.

A process 500-g may include etching the second side (e.g., the surface 560-b) of the stack 510. Etching the surface 560-b of the stack 510 may form a second staircase portion 530-b that includes a second set of tiers 525 including a tier 525-d, a tier 525-e, and a tier 525-f. The process 500-b may include exposing a respective surface of each tier 525 of the second set of tiers 525. Additionally, or alternatively, the process 500-g may include etching the second subset of the set of word lines 535 including the word line 535-d, the word line 535-e, and the word line 535-f. That is, the word line 535-d may correspond to (e.g., be located at) the tier 525-d, the word line 535-e may correspond to (e.g., be located at) the tier 525-e, and the word line 535-f may correspond to (e.g., be located at) the tier 525-f. The respective surfaces of each tier 525 may be contact surfaces, which may be used (e.g., at process 500-h, as described with reference to FIG. 5H) as landing pads for conductive pillars that couple each tier 525 (e.g., each word line 535) with supporting circuitry. The process 500-g of etching the second side may be different than the process 500-b for etching the first side because the materials in the stack are different. During the process 500-b, the stack includes alternating layers of nitride and oxide. After the replacement gate process, the stack includes alternating layers of metal (e.g., tungsten) and oxide. The process 500-g may include techniques to selected etch through metal and oxide.

A process 500-h may include forming a second set of conductive pillars 550 coupled with the second subset of the set of word lines 535. The second set of conductive pillars 550 may include a conductive pillar 550-d, a conductive pillar 550-e, and a conductive pillar 550-f, among other conductive pillars 550. The second set of conductive pillars 550 may be coupled with the second subset of the set of word lines 535. For example, the conductive pillar 550-d may be coupled with the word line 535-d, the conductive pillar 550-e may be coupled with the word line 535-e, and the conductive pillar 550-f may be coupled with the word line 535-f. Each conductive pillar 550 of the second set of conductive pillars 550 may extend from a respective tier 525 of the second set of tiers 525 along the z-direction toward a surface 560-b of the stack 510 (e.g., extending in a direction opposite the first set of conductive pillars 550). In an example, the conductive pillar 550-d may extend from the tier 525-a along the z-direction toward the surface 560-a of the stack 510.

The conductive pillar 550-a may be coplanar (e.g., vertically coplanar) with the conductive pillar 550-d. That is, at least the conductive pillar 550-a and the conductive pillar 550-d may be generally vertically aligned such that they both extend in a same plane (e.g., a zy-plane extending along the z-direction). The conductive pillar 550-a may extend away from the stack 510 (e.g., away from the tier 525-a) in the z-direction (e.g., orthogonal to the x-direction, along which the word line 535-a extends) toward the surface 560-a of the stack 510 and the conductive pillar 550-d may extend away from the stack 510 (e.g., away from the tier 525-d) along the z-direction toward the surface 560-b of the stack 510.

In some examples, the process 500-h may include forming a second conductive path between each of the second set of conductive pillars 550 and the circuitry (e.g., a CMOS 405, as described with reference to FIG. 4). The second conductive path may extend through the via 545 (e.g., from the surface 560-b through to the surface 560-a). The circuitry may be adjacent to the surface 560-a.

By forming the staircase portion 530-a and the staircase portion 530-b on either side of the stack 510 (e.g., a double-sided staircase), the described techniques may support space savings in a memory device (e.g., a memory device 100 as described with reference to FIG. 1). In some cases, the relative space savings may be illustrated in FIG. 5H with reference to a single-sided staircase architecture. For example, a single-sided staircase architecture may include relatively longer word lines 535 than the architecture described with reference to FIGS. 5A-5H. A single-sided staircase architecture may include a word line 535-h, and thus a relative distance between 535-h and the shortest word line 535 (e.g., word line 535-g) in the stack 510 may be a distance 565-c.

As described herein, in a double-sided staircase architecture, the relative distance between the longest word line 535 (e.g., word line 535-a, word line 535-d) in the stack 510 and the shortest word line 535 (e.g., word line 535-g) in the stack 510 may be a distance 565-b, which may be relatively shorter than the distance 565-c. In some instances, distance 565-b may be approximately half of the distance 565-c, and thus the memory device described herein may occupy approximately half the space of conventional memory devices.

By shortening the distance between the shortest and longest word line 535 in the stack 510, a distance 565-a (e.g., a horizontal distance) may be unused or otherwise available for additional components or circuitry. Accordingly, the distance 565-a may represent a space savings incurred by the double-sided staircase, and the distance 565-a may be utilized by the memory device to support an increased quantity of string drivers, an increased size of supporting circuitry (e.g., error correction circuitry) to support an increased accuracy or efficiency of access of memory cells, an increased memory size supporting a greater memory capacity, or a combination thereof. Moreover, reducing the distance between the shortest and longest word line 535 in the stack 510 may support an increased uniformity of word line performance (e.g., reduced variation between word lines 535), which may support an increased accuracy of access operations associated with the word lines 535, among other advantages.

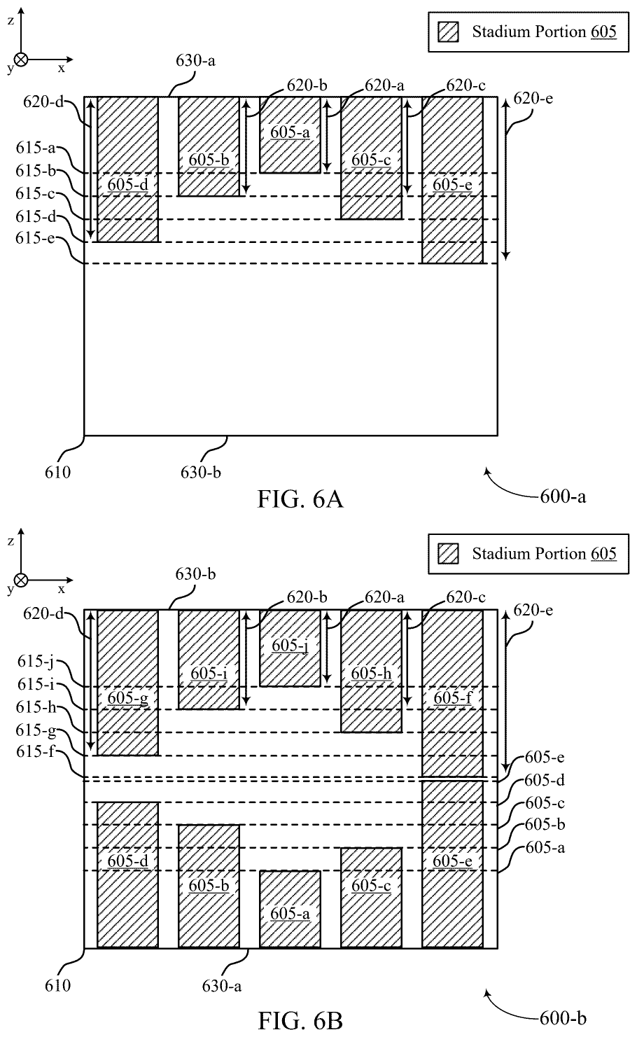

FIGS. 6A and 6B show examples of processes 600 that support memory device staircase formation in accordance with examples as disclosed herein. The processes 600 may implement or may be implemented by aspects of the memory device 100 or the memory architecture 200. For example, the processes 600 may support formation of word lines after exhuming the nitride material 515 and inserting conductive material in cavities left by the nitride material 515, which may be examples of word lines 265 as described with reference to FIGS. 2 and 3. The processes 600 may be utilized in 3D NAND memory architectures. Alternatively, the processes 600 may be utilized in 3D DRAM, VIX, or other memory architectures. Elements of the processes 600 may be described relative to an x-direction, a y-direction, and a z-direction, as illustrated in each of FIGS. 5A and 5B. The processes 600 described herein describe possible implementations, and the operations and the steps associated with the processes 600 may be rearranged or otherwise modified and other implementations are possible. Further, portions from two or more of the processes 600 may be combined.

A process 600-a may include etching stadium portions 605 into a surface 630-a of the stack 610. Stadium portions 605 may be (or otherwise refer to) cavities (e.g., a generally rectangular shape with dimensions in the x, y, and z directions) that, when combined with one or more staircase portions 530, as described with reference to FIGS. 5A-5H, form a stadium (e.g., a stadium region) that includes contact surfaces (e.g., tiers) for multiple word lines 615615 (e.g., layers) of the stack 610. For example, the process 600-a may include etching a stadium portion 605-a into the surface 630-a of the stack 610. The stadium portion 605-a may be etched to a depth 620-a (e.g., in the z-direction) corresponding to a word line 615-a. In some examples, one or more staircase portions, as described with reference to FIGS. 5A-5H, may be formed at (e.g., above, below, or on either side of) the stadium portion 605-a to form contact surfaces of a set of word lines 615, including the word line 615-a and one or more word lines 615 positioned between the word line 615-a and the surface 630-a. In some examples, a stadium may include a stadium portion 605 and one or more (e.g., two) staircase portions that may be mirrored across the z-axis (e.g., as described in greater detail with reference to FIG. 4). The two staircase portions of the stadium may each be formed at different depths to form contact surfaces of different word lines 615 of the stack 610. In some examples, the two staircase portions may be formed at either sidewall of a stadium portion 605. Additionally, or alternatively, each stadium may correspond to any quantity of staircase portions, tiers, word lines, etc.

The process 600-a may also include etching a stadium portion 605-b into the surface 630-a of the stack 610. The stadium portion 605-b may be etched to a depth 620-b (e.g., in the z-direction), greater than the depth 620-a, corresponding to the word line 615-b. One or more staircase portions, as described with reference to FIGS. 5A-5H, may be formed at (e.g., above, below, or on either side of) the stadium portion 605-b to form a stadium that includes contact surfaces (e.g., tiers) of a set of word lines 615, including the word line 615-b and one or more word lines 615 positioned between (e.g., layered between) the word line 615-b and the word line 615-a. The process 600-a may also include etching a stadium portion 605-c to a depth 620-c, greater than the depths 620-a and 620-b, corresponding to a word line 615-c, etching a stadium portion 605-d to a depth 620-d, greater than the depths 620-a through 620-c, corresponding to the word line 615-d, and etching a stadium portion 605-e to a depth 620-e, greater than the depths 620-a through 620-d, corresponding to a word line 615-e.

A process 600-b may include etching stadium portions 605 into a surface 630-b of the stack 610. For example, the stadium portion 605-j may be etched opposite the stadium portion 605-j (e.g., such that the stadium portion 605-a and the stadium portion 605-j are aligned on a same zy-plane). The stadium portion 605-a and the stadium portion 605-j may both have the same depth 620-a in the z-direction, and the stadium portion 605-j may correspond to the word line 615-j. One or more staircase portions formed at, or with, the stadium portion 605-j may (e.g., collectively) form a stadium that includes contact surfaces for the word line 615-j and one or more word lines 615 between the word line 615-j and the surface 630-b of the stack 610. The process 600-b may also include etching the stadium portion 605-i, which may be formed opposite the stadium portion 605-b and may correspond to a word line 615-i, etching the stadium portion 605-h, which may be formed opposite the stadium portion 605-c and may correspond to a word line 615-h, etching the stadium portion 605-g, which may be formed opposite the stadium portion 605-d and may correspond to a word line 615-g, and etching the stadium portion 605-f, which may be formed opposite the stadium portion 605-e and may correspond to a word line 615-f. In some examples, the stadium portions 605 may be distributed over the stack 610 in the x-direction (e.g., as shown), in the y-direction, or any combination thereof. The stadium portions 605 may support a formation of stadium regions (e.g., stadiums) in the stack 610 that each include contact surfaces for subsets of word lines 615 (e.g., a range of word lines 615) such that each word line 615 of the stack 610 has a corresponding contact surface.

In some examples, the process 600-b may also include (e.g., before etching the stadium portions 605), rotating the stack 610 (e.g., similar to the process 400-f, described with reference to FIG. 5F) such that the surface 630-b of the stack 610 is exposed for processing. In some examples, the stack 610 may be rotated approximately 180 degrees such that the surface 630-b is exposed. In other examples, the stack 610 may be rotated slightly more or slightly less than 180 degrees.

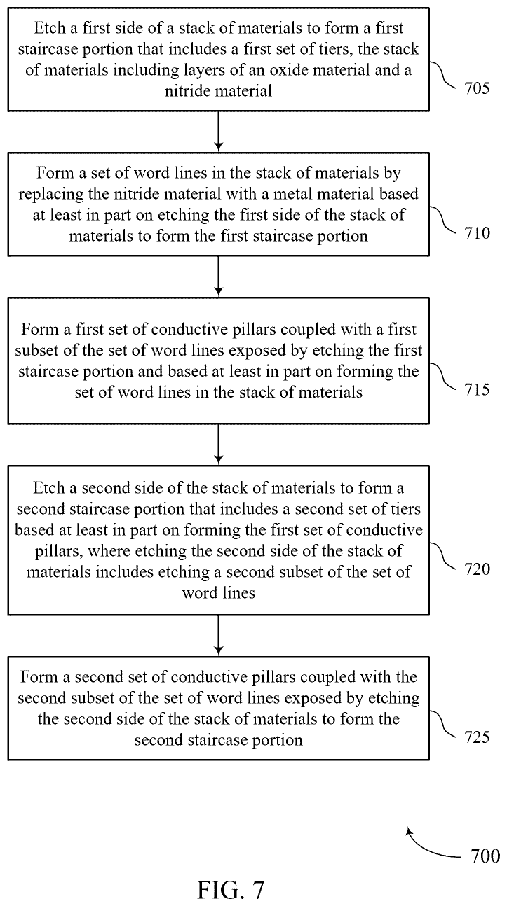

FIG. 7 shows a flowchart illustrating a method 700 that supports memory device staircase formation in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include etching a first side of a stack of materials to form a first staircase portion that includes a first set of tiers, the stack of materials including layers of an oxide material and a nitride material.

At 710, the method may include forming a set of word lines in the stack of materials by replacing the nitride material with a metal material based at least in part on etching the first side of the stack of materials to form the first staircase portion.

At 715, the method may include forming a first set of conductive pillars coupled with a first subset of the set of word lines exposed by etching the first staircase portion and based at least in part on forming the set of word lines in the stack of materials.

At 720, the method may include etching a second side of the stack of materials to form a second staircase portion that includes a second set of tiers based at least in part on forming the first set of conductive pillars, where etching the second side of the stack of materials includes etching a second subset of the set of word lines.

At 725, the method may include forming a second set of conductive pillars coupled with the second subset of the set of word lines exposed by etching the second side of the stack of materials to form the second staircase portion.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for etching a first side of a stack of materials to form a first staircase portion that includes a first set of tiers, the stack of materials including layers of an oxide material and a nitride material; forming a set of word lines in the stack of materials by replacing the nitride material with a metal material based at least in part on etching the first side of the stack of materials to form the first staircase portion; forming a first set of conductive pillars coupled with a first subset of the set of word lines exposed by etching the first staircase portion and based at least in part on forming the set of word lines in the stack of materials; etching a second side of the stack of materials to form a second staircase portion that includes a second set of tiers based at least in part on forming the first set of conductive pillars, where etching the second side of the stack of materials includes etching a second subset of the set of word lines; and forming a second set of conductive pillars coupled with the second subset of the set of word lines exposed by etching the second side of the stack of materials to form the second staircase portion.

Aspect 2: The method or apparatus of aspect 1, further including operations, features, circuitry, logic, means, or instructions, or any combination thereof for rotating the stack of materials such that the second side is exposed for processing based at least in part on forming the first set of conductive pillars, where etching the second side is based at least in part on rotating the stack of materials.

Aspect 3: The method or apparatus of any of aspects 1 through 2, where each pillar of the first set of conductive pillars extends from a respective tier of the first set of tiers in a first direction toward a first surface of the stack of materials and each pillar of the second set of conductive pillars extends from a respective tier of the second set of tiers in a second direction toward a second surface of the stack of materials opposite the first surface.

Aspect 4: The method or apparatus of aspect 3, where the first set of conductive pillars includes a first conductive pillar that is coplanar with a second conducive pillar of the second set of conductive pillars and the first conductive pillar extends away from the stack of materials in the first direction relative to a first word line of the first subset of the set of word lines and the second conducive pillar extends away from the stack of materials in the second direction relative to a second word line of the second subset of the set of word lines.

Aspect 5: The method or apparatus of any of aspects 1 through 4, further including operations, features, circuitry, logic, means, or instructions, or any combination thereof for forming the stack of materials including alternating layers of the oxide material and the nitride material, where etching the first side of the stack of materials to form the first staircase portion is based at least in part on forming the stack of materials.

Aspect 6: The method or apparatus of any of aspects 1 through 5, further including operations, features, circuitry, logic, means, or instructions, or any combination thereof for etching through a first surface of the stack of materials to form a through dielectric via; forming a first conductive path between each of the first set of conductive pillars and circuitry to access memory cells that is adjacent to a second surface of the stack of materials; and forming a second conductive path between each of the second set of conductive pillars and the circuitry, where the second conductive path extends through the through dielectric via.

Aspect 7: The method or apparatus of any of aspects 1 through 6, where etching the stack of materials to form the first staircase portion and the second staircase portion includes operations, features, circuitry, logic, means, or instructions, or any combination thereof for exposing a respective surface of each tier of the first set of tiers and exposing a respective surface of each tier of the second set of tiers.

Aspect 8: The method or apparatus of any of aspects 1 through 7, where each conductive pillar of the first set of conductive pillars contacts a respective word line of the first subset of the set of word lines in a first stadium region of the stack of materials.

Aspect 9: The method or apparatus of aspect 8, where each conductive pillar of the second set of conductive pillars contacts a respective word line of the second subset of the set of word lines in a second stadium region of the stack of materials.

Aspect 10: The method or apparatus of any of aspects 1 through 9, where each tier of the first set of tiers is located at a different depth relative to a first surface of the stack of materials and each tier of the second set of tiers is located at a different depth relative to a second surface of the stack of materials.

Aspect 11: The method or apparatus of any of aspects 1 through 10, where forming the set of word lines includes operations, features, circuitry, logic, means, or instructions, or any combination thereof for performing a metallization process to remove the nitride material from the stack of materials and form a set of metal layers.

Aspect 12: The method or apparatus of aspect 11, where performing the metallization process further includes operations, features, circuitry, logic, means, or instructions, or any combination thereof for forming a set of cavities based at least in part on removing the nitride material and depositing the metal material in each cavity of the set of cavities to form the set of metal layers.

Aspect 13: The method or apparatus of any of aspects 1 through 11, where forming the first set of conductive pillars or the second set of conductive pillars, or both is in accordance with a wafer-on-wafer bonding process.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: An apparatus, including: a stack of materials including layers of an oxide material and a set of word lines, the stack of materials including a first staircase portion and a second staircase portion opposite the first staircase portion, the first staircase portion including: a first conductive pillar coupled with a first word line of a first subset of a set of word lines, where the first conductive pillar extends, in a first plane, from the first word line toward a first surface of the stack of materials; and the second staircase portion including: a second conductive pillar coupled with a second word line of a second subset of the set of word lines, where the second conductive pillar extends, in the first plane, from the second word line toward a second surface of the stack of materials that is opposite the first surface of the stack of materials.

Aspect 15: The apparatus of aspect 14, further including: a first array portion including a first set of memory cells, where each memory cell of the first set of memory cells is coupled with a word line of the first subset of the set of word lines; and a second array portion including a second set of memory cells, where each memory cell of the second set of memory cells is coupled with a word line of the second subset of the set of word lines.

Aspect 16: The apparatus of any of aspects 14 through 15, further including: circuitry to access memory cells positioned adjacent to the second surface of the stack of materials and coupled with each of the first conductive pillar and the second conductive pillar.

Aspect 17: The apparatus of aspect 16, further including: a through dielectric via extending through the stack of materials, where the second conductive pillar is coupled with the circuitry through the through dielectric via.

Aspect 18: The apparatus of any of aspects 14 through 17, where the first staircase portion includes a first set of tiers associated with the first subset of the set of word lines, and the second staircase portion includes a second set of tiers associated with the second subset of the set of word lines.

Aspect 19: The apparatus of aspect 18, further including: a first set of conductive pillars that are each coupled with a respective tier of the first set of tiers, where each conductive pillar of the first set of conductive pillars includes a respective height that is based on a location of a tier of the first set of tiers to which it is coupled; and a second set of conductive pillars that are each coupled with a respective tier of the second set of tiers, where each conductive pillar of the second set of conductive pillars includes a respective height that is based on a location of a tier of the second set of tiers to which it is coupled.

Aspect 20: The apparatus of any of aspects 14 through 19, where the first conductive pillar is vertically aligned with the second conductive pillar.

Aspect 21: The apparatus of any of aspects 14 through 20, where each conductive pillar of the first set of conductive pillars is coplanar with a respective conductive pillar of the second set of conductive pillars.

Aspect 22: The apparatus of any of aspects 14 through 20, further including: a first stadium region, where the first conductive pillar contacts the first word line in a first stadium region of the stack of materials.

Aspect 23: The apparatus of aspect 22, further including: a second stadium region, where the second conductive pillar contacts the second word line in a second stadium region of the stack of materials.

An apparatus is described. The following provides an overview of aspects of the apparatus as described herein:

Aspect 24: An apparatus, including: a first conductive pillar coupled with a first word line that extends in a first direction, where the first conductive pillar extends through a stack of materials in a second direction orthogonal to the first direction; a second conductive pillar coupled with a second word line that extends in the first direction, where the second conductive pillar extends through the stack of materials in a third direction that is opposite the second direction and orthogonal to the first direction; and circuitry to access memory cells coupled with the first conductive pillar and the second conductive pillar and configured to perform one or more operations on an array of memory cells associated with the stack of materials.

Aspect 25: The apparatus of aspect 24, where the first conductive pillar includes a first length and the first word line includes a second length, the apparatus further including: a third conductive pillar coupled with a third word line extending in the first direction, the third word line including a third length different than the second length, where the third conductive pillar extends in the second direction and includes a fourth length different than the first length.

Aspect 26: The apparatus of aspect 25, where the second conductive pillar includes a fifth length and the second word line includes a sixth length, the apparatus further including: a fourth conductive pillar coupled with a fourth word line extending in the first direction, the fourth word line including a seventh length different than the sixth length, where the fourth conductive pillar extends in the third direction and includes an eight length different than the fifth length.

Aspect 27: The apparatus of any of aspects 24 through 26, where first conductive pillar is coplanar with the second conductive pillar, and where the third conductive pillar is coplanar with the fourth conductive pillar.

Aspect 28: The apparatus of any of aspects 24 through 27, further including: a first stadium region, where the first conductive pillar contacts the first word line in a first stadium region of the stack of materials.

Aspect 29: The apparatus of aspect 28, further including: a second stadium region, where the second conductive pillar contacts the second word line in a second stadium region of the stack of materials.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open- ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a stack of materials comprising layers of an oxide material and a set of word lines, the stack of materials comprising a first staircase portion and a second staircase portion opposite the first staircase portion,
the first staircase portion comprising:
a first conductive pillar coupled with a first word line of a first subset of a set of word lines, wherein the first conductive pillar extends, in a first plane, from the first word line toward a first surface of the stack of materials; and
the second staircase portion comprising:
a second conductive pillar coupled with a second word line of a second subset of the set of word lines, wherein the second conductive pillar extends, in the first plane, from the second word line toward a second surface of the stack of materials that is opposite the first surface of the stack of materials.

2. The apparatus of claim 1, further comprising:
a first array portion comprising a first set of memory cells, wherein each memory cell of the first set of memory cells is coupled with a word line of the first subset of the set of word lines; and
a second array portion comprising a second set of memory cells, wherein each memory cell of the second set of memory cells is coupled with a word line of the second subset of the set of word lines.

3. The apparatus of claim 1, further comprising:
circuitry to access memory cells positioned adjacent to the second surface of the stack of materials and coupled to each of the first conductive pillar and the second conductive pillar.

4. The apparatus of claim 3, further comprising:
a through dielectric via extending through the stack of materials, wherein the second conductive pillar is coupled with the circuitry through the through dielectric via.

5. The apparatus of claim 1, wherein the first staircase portion comprises a first set of tiers associated with the first subset of the set of word lines, and wherein the second staircase portion comprises a second set of tiers associated with the second subset of the set of word lines.

6. The apparatus of claim 5, further comprising:
a first set of conductive pillars that are each coupled with a respective tier of the first set of tiers, wherein each conductive pillar of the first set of conductive pillars comprises a respective height that is based on a location of a tier of the first set of tiers to which it is coupled; and
a second set of conductive pillars that are each coupled with a respective tier of the second set of tiers, wherein each conductive pillar of the second set of conductive pillars comprises a respective height that is based on a location of a tier of the second set of tiers to which it is coupled.

7. The apparatus of claim 6, wherein each conductive pillar of the first set of conductive pillars is coplanar with a respective conductive pillar of the second set of conductive pillars.

8. The apparatus of claim 1, wherein the first conductive pillar is vertically aligned with the second conductive pillar.

9. The apparatus of claim 1, wherein the first conductive pillar contacts the first word line in a first stadium region of the stack of materials.

10. The apparatus of claim 9, wherein the second conductive pillar contacts the second word line in a second stadium region of the stack of materials.

11. An apparatus, comprising:
a first conductive pillar coupled with a first word line that extends through a stack of materials in a first direction, wherein the first conductive pillar extends in a second direction;
a second conductive pillar coupled with a second word line that extends through the stack of materials in the first direction, wherein the second conductive pillar extends in a third direction opposite the second direction; and
circuitry to access memory cells coupled with the first conductive pillar and the second conductive pillar and configured to perform one or more operations on an array of memory cells associated with the stack of materials.

12. The apparatus of claim 11, wherein the first conductive pillar comprises a first length and the first word line comprises a second length, the apparatus further comprising:
a third conductive pillar coupled with a third word line extending in the first direction, the third word line comprising a third length different than the second length, wherein the third conductive pillar extends in the second direction and comprises a fourth length different than the first length.

13. The apparatus of claim 12, wherein the second conductive pillar comprises a fifth length and the second word line comprises a sixth length, the apparatus further comprising:
a fourth conductive pillar coupled with a fourth word line extending in the first direction, the fourth word line comprising a seventh length different than the sixth length, wherein the fourth conductive pillar extends in the third direction and comprises an eight length different than the fifth length.

14. The apparatus of claim 13, wherein the first conductive pillar is coplanar with the second conductive pillar, and wherein the third conductive pillar is coplanar with the fourth conductive pillar.

15. The apparatus of claim 11, wherein the first conductive pillar contacts the first word line in a first stadium region of the stack of materials.

16. The apparatus of claim 15, wherein the second conductive pillar contacts the second word line in a second stadium region of the stack of materials.

17. A method, comprising:
etching a first side of a stack of materials to form a first staircase portion that comprises a first set of tiers, the stack of materials comprising layers of an oxide material and a nitride material;
forming a set of word lines in the stack of materials by replacing the nitride material with a metal material based at least in part on etching the first side of the stack of materials to form the first staircase portion;
forming a first set of conductive pillars coupled with a first subset of the set of word lines exposed by etching the first staircase portion and based at least in part on forming the set of word lines in the stack of materials;
etching a second side of the stack of materials to form a second staircase portion that comprises a second set of tiers based at least in part on forming the first set of conductive pillars, wherein etching the second side of the stack of materials comprises etching a second subset of the set of word lines; and
forming a second set of conductive pillars coupled with the second subset of the set of word lines exposed by etching the second side of the stack of materials to form the second staircase portion.

18. The method of claim 17, further comprising:
rotating the stack of materials such that the second side is exposed for processing based at least in part on forming the first set of conductive pillars, wherein etching the second side is based at least in part on rotating the stack of materials.

19. The method of claim 17, wherein:
each pillar of the first set of conductive pillars extends from a respective tier of the first set of tiers in a first direction toward a first surface of the stack of materials; and
each pillar of the second set of conductive pillars extends from a respective tier of the second set of tiers in a second direction toward a second surface of the stack of materials opposite the first surface.

20. The method of claim 19, wherein the first set of conductive pillars comprises a first conductive pillar that is coplanar with a second conducive pillar of the second set of conductive pillars, wherein the first conductive pillar extends away from the stack of materials in the first direction relative to a first word line of the first subset of the set of word lines and the second conducive pillar extends away from the stack of materials in the second direction relative to a second word line of the second subset of the set of word lines.
